(19) United States
(12) Patent Application Publication
(10) Pub. No.: US 2002/0170495 A1
(43) Pub. Date: Nov. 21, 2002

(54) Method for fabricating a thin film and apparatus for fabricating a thin film

(75) Inventors: Yukinori Nakamura, Nagoya City (JP); Yoshimasa Kondo, Nagoya City (JP); Naoto Otake, Yokosuka City (JP)

Correspondence Address: BURR & BROWN, PO BOX 7068, SYRACUSE, NY, 13261-7068, US

(73) Assignee: NGK Insulators, Ltd., Nagoya City (JP)

(21) Appl. No.: 10/144,505

(22) Filed: May 13, 2002

Related U.S. Application Data
(60) Provisional application No. 60/301,035, filed on Jun. 26, 2001.

(30) Foreign Application Priority Data
May 17, 2001 (JP) 2001-147,766

(51) Int. Cl. H05H 1/24; C23C 16/00

(52) U.S. Cl. 118/715; 118/723 R; 427/569

(57) ABSTRACT

The back side space of a tubular member is evacuated by means of a pressure difference-creating means constructed of a pressure regulating chamber and a pump, and then, the pressure in the back side space of the tubular member is set to be tenth or below of the pressure in the front space of the tubular member. Then, a raw material gas is introduced and excited to generate a plasma raw material gas, which is introduced into the tubular member and onto an inner wall of the tubular member, efficiently commensurate with the pressure difference created by means of the pressure difference-creating means. As a result, a desired thin film is formed on the inner wall of the tubular member through the chemical reaction of the plasma raw material gas.

### BACKGROUND OF THE INVENTION

1. Field of the Invention

This invention relates to a method for fabricating a thin film and an apparatus for fabricating a thin film which are preferably usable as a coating means of thin film having a wear-resistance for an inner wall of a tubular product.

2. Description of the Prior Art

Conventionally, such an attempt is made as to form a hard thin film made of diamond or diamond like carbon on a given base material to make a wear-resistance product. Recently, such an attempt is made as to form the hard thin film on an inner wall of a given tubular member to fabricate a wear-resistance tubular product which is available for various applications.

The hard thin film made of diamond or the like is fabricated by means of a plasma CVD method where a raw material gas such as methane is introduced into a plasma reactor with a carrier gas and then, excited by means of microwave or high frequency wave, to generate a plasma raw material gas, which is chemically reacted on a given base material. Although a hard thin film made of diamond or the like can be formed uniformly for a simply shaped member such as a plate, however, it can not be almost formed for a complicatedly shaped member such as an inner wall of a tubular member because of the insufficient introduction of the plasma raw material gas into the tubular member.

In this point of view, such an attempt is made in Japanese Patent Application Laid-open No. 62-136569 as to set an electrode made of graphite and then, generate a plasma raw material gas from a given raw material gas directly in a tubular member. According to this technique, a large amount of plasma raw material gas can be supplied into the tubular member, so that a thicker hard thin film made of diamond or the like can be formed in the inner wall of the tubular member easily and uniformly.

It is required, however, in the above-mentioned technique that the size of the graphite electrode is set to be smaller than the inner diameter of the tubular member, which is quite difficult as the size of the tubular member becomes extremely small. Moreover, in the case of preparing plural tubular members and forming hard thin films in the tubular members, respectively, it is required that plural graphite electrodes are prepared in the tubular members, respectively. In this case, the entire structure of the plasma CVD apparatus becomes complicated and thus, the fabricating process of hard thin film also becomes complicated.

### SUMMERY OF THE INVENTION

It is an object of the present invention to provide a film-forming means whereby a thin film can be easily formed on an inner wall of a tubular member irrespective of the size of the inner wall and plural thin films can be also easily formed on respective inner walls of plural tubular members, simultaneously.

For achieving the above object, this invention relates to a method for fabricating a thin film, comprising the steps of:

preparing a plasma CVD apparatus,

setting a tubular member in the plasma CVD apparatus,

creating a pressure difference along a long direction of the tubular member, to introduce a plasma raw material gas into the tubular member commensurate with the pressure difference, and

chemically reacting the plasma raw material gas on an inner wall of the tubular member to fabricate a thin film on the inner wall.

Also, this invention relates to an apparatus for fabricating a thin film on an inner wall of a tubular member, comprising:

a given plasma CVD apparatus, and

a pressure difference-creating means to create a given pressure difference along a long direction of the tubular member,

wherein a given plasma raw material gas is introduced into the tubular member commensurate with the pressure difference.

The inventors had intensely studied to attain the above object, and as a result, found out that a pressure difference is created in a long direction of a tubular member on which a given thin film is formed, and a given plasma raw material gas, which is generated through the excitation of a raw material gas, is introduced into the tubular member commensurate with the pressure difference.

According to a conventional plasma CVD method, a given raw material gas is introduced into a plasma reactor and then, excited in plasma state. The thus obtained plasma raw material gas is supplied onto an inner wall of a tubular member commensurate with the convection of the raw material gas. On the contrary, according to the fabricating method and the fabricating apparatus of the present invention, a pressure difference is created along a long direction of a tubular member by means of a pressure difference-creating means, and a plasma raw material gas is supplied onto an inner wall of a tubular member commensurate with the pressure difference.

Therefore, according to the present invention, a large amount of plasma raw material gas can be supplied onto the inner wall of the tubular member, and then, chemically reacted sufficiently. As a result, a desired thin film can be easily formed on the inner wall.

Also, according to the present invention, the plasma raw material gas can be efficiently introduced into the tubular member having an extremely small size of inner diameter, so a desired thin film can be easily formed on an inner wall of the tubular member of small inner diameter.

Moreover, without electrodes, desired thin films can be easily formed in inner walls of plural tubular members simultaneously, so that the film-forming efficiency of thin film can be enhanced.

In a preferred embodiment, a magnetic field-generating means is provided to generate a given magnetic field along a long direction of a tubular member, and a plasma raw material gas is introduced into a tubular member with trapped by the magnetic field. In this case, a large amount of plasma raw material gas can be introduced into the tubular member efficiently.

In another preferred embodiment, an electric field-generating means is provided to generate an electric field along a long direction of a tubular member, and a plasma raw material gas is introduced into the tubular member commensurate with the electric field. In this case, too, a large amount of plasma raw material gas can be introduced into the tubular member efficiently.

The plasma raw material gas can be generated from the raw material gas by means of the electric field-generating means. In this case, additional exciting means is not required to generate the plasma raw material gas, so that the entire structure of the fabricating apparatus can be simplified and the fabricating process can be also simplified.

### BRIEF DESCRIPTION OF THE DRAWINGS

For a better understanding of the invention, reference is made to the accompanying drawings:

FIG. 1 is a structural view schematically showing a fabricating apparatus of thin film according to the present invention, and FIG. 2 is a graph showing a Raman spectrum of a diamond-like carbon thin film fabricated according to the fabricating method and the fabricating apparatus of the present invention.

### DESCRIPTION OF THE PREFERRED EMBODIMENTS

The invention will be described in detail below, with reference to the above drawings.

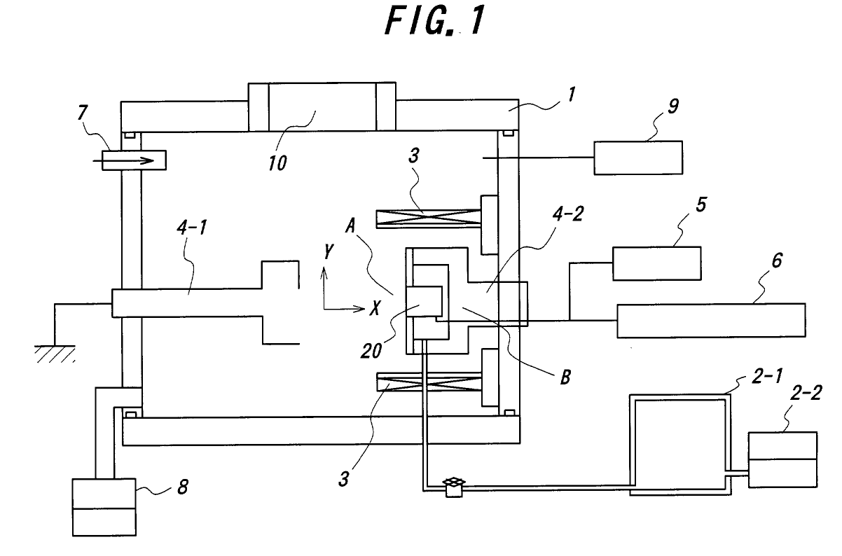

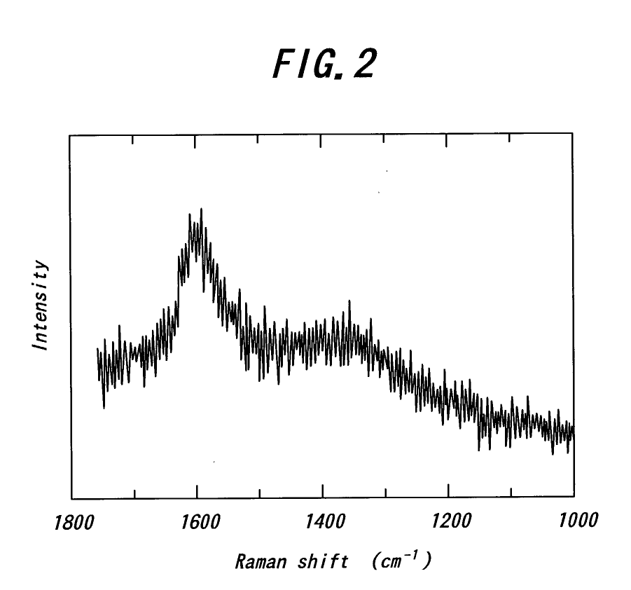

FIG. 1 is a schematic view showing a fabricating apparatus of thin film according to the present invention. The fabricating apparatus includes a film-forming chamber 1, a pressure-regulating chamber 2-1 and a pump 2-2 as a pressure difference-creating means which are connected to the chamber 1, a coil 3 as a magnetic field-generating means, a positive electrode 4-1 and negative electrode 4-2 as an electric field-generating means. The positive electrode 4-1 is grounded, and the negative electrode 4-2 is connected to a DC power supply 5 and a high pressure-pulsed voltage power supply 6.

At the chamber 11 are provided a gas inlet 7 to introduce a given raw material gas and a pump 8 as an evacuating means to maintain the chamber 11 to a predetermined degree of vacuum. Also, at the chamber 1 are provided a pressure gauge 9 and a window 10 to monitor the degree of vacuum in the chamber 1 and the condition of a plasma raw material gas made through the excitation of the raw material gas introduced. A tubular member 20 is fixed and set above the negative electrode 4-2.

A thin film is fabricated on an inner wall of the tubular member 20 as follows.

First of all, the interior of the chamber 1 is evacuated up to a predetermined degree of vacuum with the pump 8, and a given raw material gas is introduced into the chamber 1 from the gas inlet 7. Then, the introduction of the raw material gas into the chamber 1 and the evacuation for the interior of chamber 1 are balanced, to maintain the interior of the chamber 1 in a predetermined degree of vacuum. Herein, the degree of vacuum is monitored by means of the pressure gauge 9.

Then, a given pulsed voltage is applied to the tubular member 20 from the high pressure-pulsed voltage power supply 6 with applying a given DC biasing voltage to the tubular member 20 from the DC power supply 5, to excite the raw material gas in plasma state.

Then, the space around the negative electrode 4-2 where the tubular member 20 is located is evacuated via the pressure regulating chamber 2-1 by means of the pump 2-2, to create a given pressure difference in the long direction of the tubular member 20 along the X-direction. The pressure difference is preferably determined so that the pressure in the back space B of the tubular member 20 along the X-direction is set to be tenth or below, particularly centesimal or below of the pressure in the front space A of the tubular member 20 along the X-direction. In this case, the plasma raw material gas can be introduced into the tubular member 20 efficiently.

Concretely, since the pressure of the chamber 1 is set to about 10⁻² Torr and the pressure in the front space A of tubular member 20 is set to about 10⁻² Torr, the pressure in the back space B of the tubular member 20 is preferably set to a pressure within a range of 10⁻³-10⁻⁴ Torr by means of the pressure regulating chamber 2-1 and the pump 2-2.

Then, a given magnetic field is generated in the long direction of the tubular member 20 along the X-direction by flowing a current in the coil 3. The magnetic field is preferably converged in the Y-direction perpendicular to the X-direction so that the dimension of the magnetic field is set to be in the order of the inner diameter of the tubular member 20. In this case, a large amount of plasma raw material gas can be introduced into the tubular member 20, and thus, a desired thin film can be formed in a large thickness on an inner wall of the tubular member 20.

Supposed that the inner diameter of the tubular member 20 is defined as “r”, the strength of the magnetic field is preferably set to 2.0×10⁻⁷/r (T) or over. Concretely, supposed that the inner diameter “r” is set to 1.0 mm, the magnetic field is preferably set within 1.0×10⁻⁴−3.0×10⁻⁴T, particularly within 2.0×10⁻⁴-3.0×10⁻⁴T. In this case, the plasma raw material gas can be trapped by the magnetic field more efficiently, and thus, a large amount of plasma raw material gas can be introduced into the tubular member 20. As a result, the desired thin film can be formed in the inner wall of the tubular member 20 easily and efficiently.

Also, a given electric field is generated toward the positive electrode 4-1 from the negative electrode 4-2 by the DC biasing voltage and the pulsed voltage which are utilized to generate the plasma raw material gas. Therefore, the plasma raw material gas is introduced into the tubular member 20 efficiently by means of the electric field. As a result, a large amount of plasma raw material gas can be introduced into the tubular member 20, and thus, the desired thin film can be formed in the inner wall of the tubular member easily and efficiently.

The strength of the electric field is preferably set within 20-200 kV/m, particularly within 20-100 kV/m. In the fabricating apparatus shown in FIG. 1, the electric field strength of the above range can be realized by controlling the DC voltage and the pulsed voltage within given ranges to generate the plasma gas, respectively.

In the fabricating apparatus shown in FIG. 1, as mentioned above, since the magnetic field and the electric field are generated along the X-direction, in addition to the pressure difference, the plasma raw material gas can be introduced into the tubular member 20 more efficiently, so that the desired thin film can be fabricated in a large thickness on the inner wall of the tubular member 20.

The fabricating method and the fabricating apparatus of the present invention can be applied for various tubular members, irrespective of the configuration and the size of each tubular member. The bottom surface of a tubular member to be employed along the X-direction may be partially punctured so as not to prevent the introduction of a plasma raw material gas commensurate with the pressure difference. In this case, a larger amount of plasma raw material gas is introduced into the tubular member efficiently commensurate with the pressure difference, the desired thin film can be formed in a large thickness on the inner bottom surface of the tubular member efficiently.

However, the desired thin film can be formed efficiently on an inner wall of a tubular member having such an opening made at the bottom surface if the pressure difference and the magnetic field are appropriately controlled in accordance with the size of the tubular member. Therefore, the desired thin film can be formed on the inner wall and the inner bottom surface of the tubular member uniformly and efficiently.

According to the fabricating method and the fabricating apparatus of the present invention, the desired thin film can be formed on an inner wall of a tubular member having an inner diameter of 10 mm or below, particularly 1 mm or below efficiently. The lower limited inner diameter of the tubular member for which the desired thin film can be formed is 0.01 mm, particularly 0.1 mm.

Also, according to the fabricating method and the fabricating apparatus of the present invention, as mentioned above, the desired thin film is formed on by means of the pressure difference without a given electrode being prepared in the tubular member. Therefore, even though plural tubular members are prepared in the fabricating apparatus as shown in FIG. 1, thin films desired can be formed on inner walls of the tubular members, respectively, so that the film-forming efficiency can be enhanced.

Moreover, according to the fabricating method and the fabricating apparatus of the present invention, various thin films can be formed on an inner wall of a tubular member. If a thin film made of diamond or diamond-like carbon is formed in the inner wall of the tubular member, a large wear-resistance can be imparted to the tubular member.

### EXAMPLE

This invention will be described concretely hereinafter. In this Example, a tubular member of which the inner diameter is 1 mm and which has a bottom surface having a slit-shaped opening was employed. The height of the opening was 0.1 mm and the width of the opening was 40 mm. Then, an attempt is made as to fabricate a thin film made of diamond-like carbon on an inner wall of the tubular member by utilizing a fabricating apparatus as shown in FIG. 1

First of all, the tubular member 20 was fixed and set above the negative electrode 4-2, and the interior of the film-forming chamber 1 was evacuated up to 10⁻⁵ Torr by mean of the pump 8. Then, a CH₄ gas was introduced from the gas inlet 7 at a flow rate of 20 cm³/min, and then, the interior pressure of the chamber 1 was maintained at 3.75×10⁻² Torr through the evacuation by means of the pump 8. Subsequently, a voltage of 1.5 kV was applied between the positive electrode 4-1 and the negative electrode 4-2 from the DC power supply 5 and the high pressure-pulsed voltage power supply 6, to generate a CH₄ gas plasma. In this case, an electric field having a strength of 30 kV/m was generated between the positive electrode 4-1 and the negative electrode 4-2.

Then, the pressure in the back side space of the tubular member 20 along the X-direction was set to 4.5×10⁻⁴ Torr by means of the pressure regulating chamber 2-1 and the pump 2-2. Moreover, a magnetic field having a strength of 0.01T was generated along the X-direction by flowing a current in the coil 3.

The above condition was maintained for 15 minutes so that the CH₄ gas plasma was introduced into the tubular member 20 and then, a diamond-like carbon thin film was formed at an inner wall of the tubular member 20.

FIG. 2 is a graph showing a Raman spectrum of the diamond-like carbon thin film. As is apparent from FIG. 2, absorption peaks due to diamond-like carbon are observed around 1360 cm⁻¹ and 1580 cm⁻¹, so that it is turned out that the diamond-like carbon thin film is excellent in quality.

This invention has been described in detail with reference to the above preferred concrete embodiments, but it is obvious for the ordinary person skilled in the art that various modifications can be made in its configuration and detail without departing from the scope of this invention.

According to the fabricating method of thin film and the fabricating apparatus of the present invention, as mentioned above, a pressure difference is created in the long direction of a tubular member, and thus, a given plasma raw material gas is introduced by utilizing the pressure difference. Therefore, a large amount of plasma raw material gas can be introduced into the tubular member, and thus, a given thin film can be formed on an inner wall of the tubular member even though the inner diameter of the tubular member is extremely small. In addition, given thin films can be formed on inner walls of plural tubular members, respectively.

What is claimed is:

1. A method for fabricating a thin film, comprising the steps of:
preparing a plasma CVD apparatus,
setting a tubular member in said plasma CVD apparatus,
creating a pressure difference along a long direction of said tubular member, to introduce a plasma raw material gas into said tubular member commensurate with said pressure difference, and
chemically reacting said plasma raw material gas on an inner wall of said tubular member to fabricate a thin film on said inner wall.

2. A fabricating method as defined in claim 1, wherein said pressure difference is determined so that the pressure in the back side space of said tubular member is set to be tenth or below of the pressure in the front space of said tubular member.

3. A fabricating method as defined in claim 1, further comprising the step of generating a given magnetic field along said long direction of said tubular member, wherein said plasma raw material gas is introduced into said tubular member with trapped by said magnetic field.

4. A fabricating method as defined in claim 3, wherein said magnetic field is converged in a direction perpendicular to said long direction of said tubular member so that the dimension of said magnetic field is set to be in the order of the inner diameter of said tubular member.

5. A fabricating method as defined in claim 4, wherein the strength of said magnetic field is set to 2.0×10−7/r (T) or over, on condition that the minimum diameter of said tubular member is defined as “r”.

6. A fabricating method as defined in claim 1, further comprising the step of generating a given electric field along said long direction of said tubular member, wherein said plasma raw material gas is introduced into said tubular member commensurate with said electric field.

7. A fabricating method as defined in claim 6, wherein the strength of said electric field is set within 20-200 kV/m.

8. A fabricating method as defined in claim 1, wherein the inner diameter of said tubular member is set within 0.001-1 mm.

9. A fabricating method as defined in claim 1, wherein said thin film is made of diamond or diamond-like carbon.

10. An apparatus for fabricating a thin film on an inner wall of a tubular member, comprising:
a given plasma CVD apparatus, and
a pressure difference-creating means to create a given pressure difference along a long direction of said tubular member,
wherein a given plasma raw material gas is introduced into said tubular member commensurate with said pressure difference.

11. A fabricating apparatus as defined in claim 10, wherein by means of said pressure difference-creating means, the pressure in the back side space of said tubular member is set to be tenth or below of the pressure in the front space of said tubular member.

12. A fabricating apparatus as defined in claim 11, further comprising a magnetic field-generating means to generate a given magnetic field along said long direction of said tubular member, wherein said plasma raw material gas is introduced into said tubular member with trapped by said magnetic field.

13. A fabricating apparatus as defined in claim 12, wherein by means of said magnetic field-generating means, said magnetic field is converged in a direction perpendicular to said long direction of said tubular member so that the dimension of said magnetic field is set to be in the order of the inner diameter of said tubular member.

14. A fabricating apparatus as defined in claim 10, further comprising an electric field-generating means to generate a given electric field along said long direction of said tubular member, wherein said plasma raw material gas is introduced into said tubular member commensurate with said electric field.
